(19) United States
(12) Patent Application Publication
(10) Pub. No.: US 2006/0019497 A1
(43) Pub. Date: Jan. 26, 2006

(54) Reduced feature-size memory devices and methods for fabricating the same

(76) Inventors: Zhizhang Chen, Corvallis, OR (US); Sriram Ramamoorthi, Corvallis, OR (US); Hang Liao, Corvallis, OR (US)

Correspondence Address: HEWLETT-PACKARD DEVELOPMENT COMPANY;Intellectual Property Administration, P.O. Box 272400, Fort Collins, CO, 80527-2400, US

(21) Appl. No.: 10/897,178

(22) Filed: Jul. 22, 2004

(51) Int. Cl. H01L 21/302

(52) U.S. Cl. 438/689; 438/3

(57) ABSTRACT

This disclosure relates to systems and methods for reducing feature sizes. One of these methods enables formation of an original feature having a size in a length or width dimension of between about 100 and about 1000 nanometers with a system capable of patterning features to a minimum size of less than or about the size of the original feature and reduction of the size of the original feature below that of the minimum size of the system using an alignment-independent technique.

### TECHNICAL FIELD

This invention relates to systems and methods for fabricating features in memory devices.

### BACKGROUND

Photolithography and other patterning techniques are used to fabricate features of particular sizes and shapes. These features can include parts of electrical devices for instance, such as wires, channels, electrical contacts, and the like. For many reasons, the device industry desires to fabricate smaller features. Smaller features can enable devices to be smaller overall, cheaper, faster, and more robust.

To fabricate patterns having smaller and smaller features, various patterning techniques and systems have been created or improved. Advanced photolithography systems, for example, have recently been designed to fabricate patterns having features as small as one hundred nanometers. These systems are extremely expensive, however. Currently these system can cost tens of millions of dollars. Other less-advanced photolithography systems are also available some of which are typically capable of fabricating patterns having features only as small as 250 nanometers. While these systems typically cannot pattern one-hundred-nanometer features, they often cost millions less than the advanced photolithography systems.

Further, whatever the patterning technique or system used, each typically has a limit on how small it can fabricate features. As smaller and smaller features are desired, even advanced patterning techniques and systems may not be capable of fabricating features of a desired size.

There is, therefore, a need for systems and methods capable of reducing feature sizes.

### BRIEF DESCRIPTION OF THE DRAWINGS

FIG. 1 includes top-plan and clipped-plane views of a substrate having four exemplary features.

FIG. 2 includes top-plan and clipped-plane views of exemplary features and structures capable of forming part of an exemplary memory device.

FIG. 3 includes the clipped-plane view of FIG. 2 at a processing step subsequent to that shown by FIG. 2 and an expanded view.

FIG. 4 includes the top-plan view of FIG. 2 and the views of FIG. 3, all at processing steps subsequent to that shown by FIGS. 2 and 3.

FIG. 5 includes the views of FIG. 4 at a processing step subsequent to that shown by FIG. 4.

The same numbers are used throughout the disclosure and figures to reference like components and features.

### DETAILED DESCRIPTION

Overview

This document discloses systems and methods (“tools”) for reducing feature sizes. One of these tools enables a feature patterned with a relatively inexpensive system to be reduced in size to that which would otherwise be patterned with a much more expensive system. This tool enables fabrication of features at a lower cost than is otherwise typically available. Another tool reduces feature sizes below those that are typically patternable even with advanced systems. By so doing, features of very small sizes are enabled. In addition, in at least some embodiments, memory devices can be fabricated using these tools.

Patterned Features

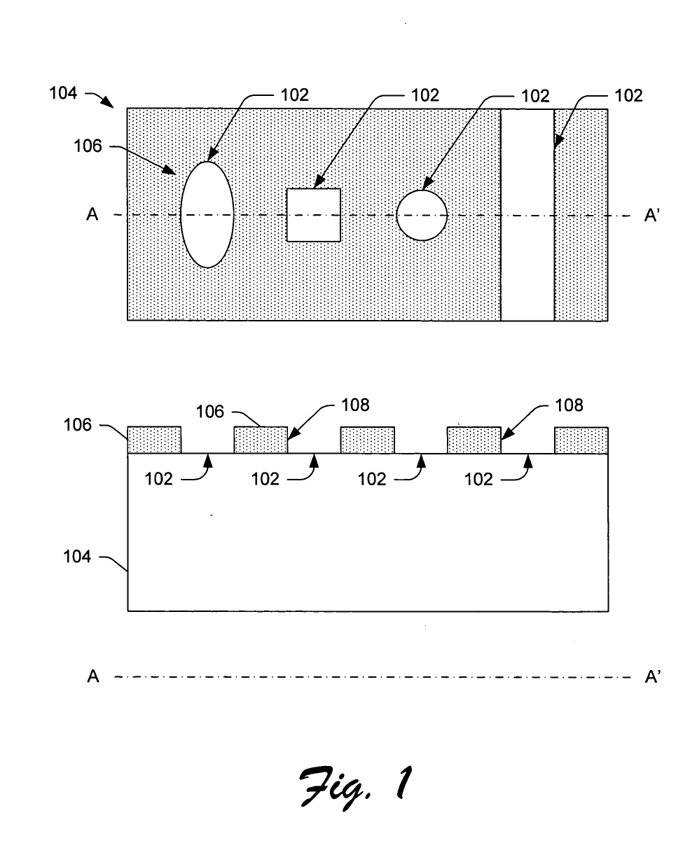

Referring initially to FIG. 1, features 102 are formed over a substrate 104. Each feature 102 can be formed utilizing photolithography, e-beam, or other suitable techniques. The individual features can comprise a variety of shapes such as a linear or non-linear channel, a square, a circle, and the like.

Each feature 102 can be defined physically by a structure 106, shown in a clipped plane view along A-A′. This structure forms the outer bounds of the feature. In the embodiment shown in FIG. 1, the structure comprises a physical boundary or wall 108 around the feature such that the feature forms a depression relative to the structure. While these physical boundaries comprise walls, other boundaries can be used.

With some exemplary features and accompanying structures set forth, the discussion now turns, for purposes of illustration, to exemplary memory devices having a feature that can be size-reduced using the tools described herein.

Fabricating an Exemplary Memory Device

In the embodiment about to be described, memory devices are fabricated, in part, with the tools to reduce the size of one or more of their features. These memory devices are set forth as examples, and are not intended to limit the applicability of the tools.

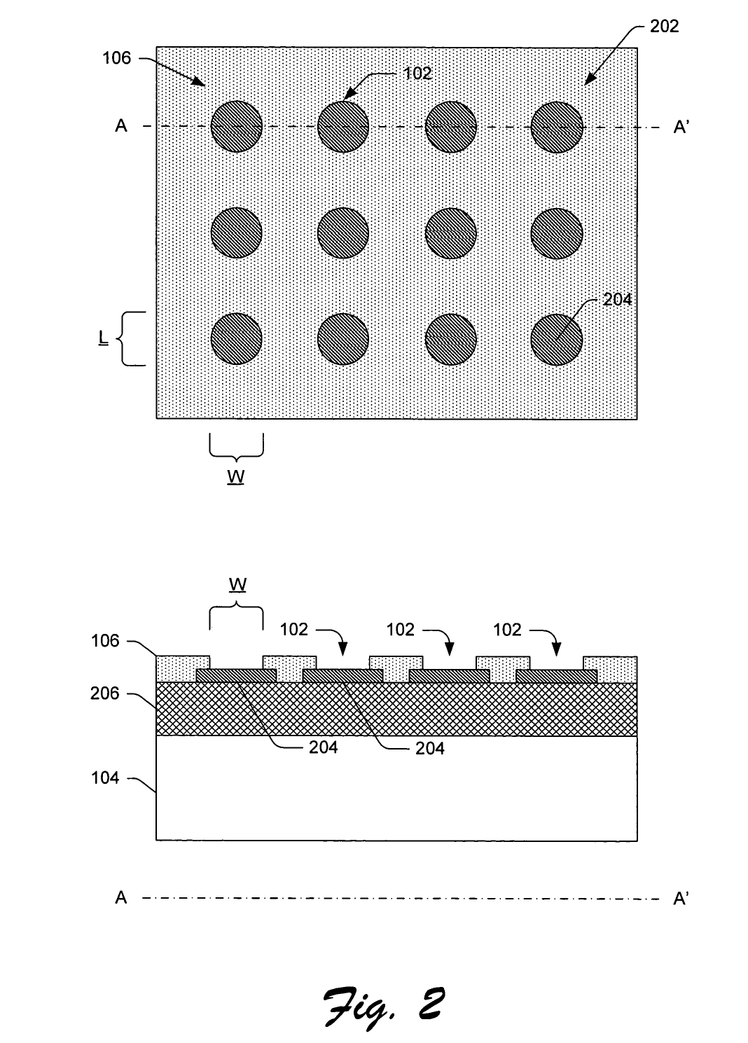

Referring to FIG. 2, a pattern 202 of features 102 is formed over an assembly of layers that include, in this example, bottom electrodes 204 disposed on an insulative layer 206 which, in turn, is disposed over substrate 104. The bottom electrodes provide electrical communication with a memory material that will eventually be formed in contact with the bottom electrodes. The bottom electrodes are formed as an array of conductive structures that will later form part of a cross-bar memory device. In this embodiment, the features 102 and accompanying structures 106 are photolithographically formed utilizing e-beam or other suitable techniques.

The features 102, in this example, are circular in shape. As with many devices, a feature's size in one or more dimensions affects the performance of the device. In the ongoing embodiment, each of the features comprises an area exposing one of the bottom electrodes. Once this area is reduced in size, the reduced area will determine how much memory material is formed in electrical communication with the bottom electrodes. Because of this, the area exposing the bottom electrodes affects the power consumption and reliability of the memory device. The smaller the area, generally the better the memory device performs.

Prior to reducing the size of features 102, the features have lengths L and widths W shown in the top plan view. The widths are also shown in a clipped-plane view along the line A-A′. In this example, each of the features has the same width and length (because the shape of each feature is circular), though with many other shapes this is not the case.

In the ongoing embodiment, the width and the length of each of the features is about 250 nanometers. These dimensions of the features are those typically capable of being formed with less advanced photolithography and using techniques that will be appreciated by the skilled artisan. Other sizes, such as widths and lengths of about 100 nanometers can also be formed, such as with more-advanced photolithography.

Reducing Feature Size

Exemplary processes by which one or more feature sizes can be reduced are set forth below. These processes can comprise alignment-independent techniques, such as thin-film deposition and anisotropic etching.

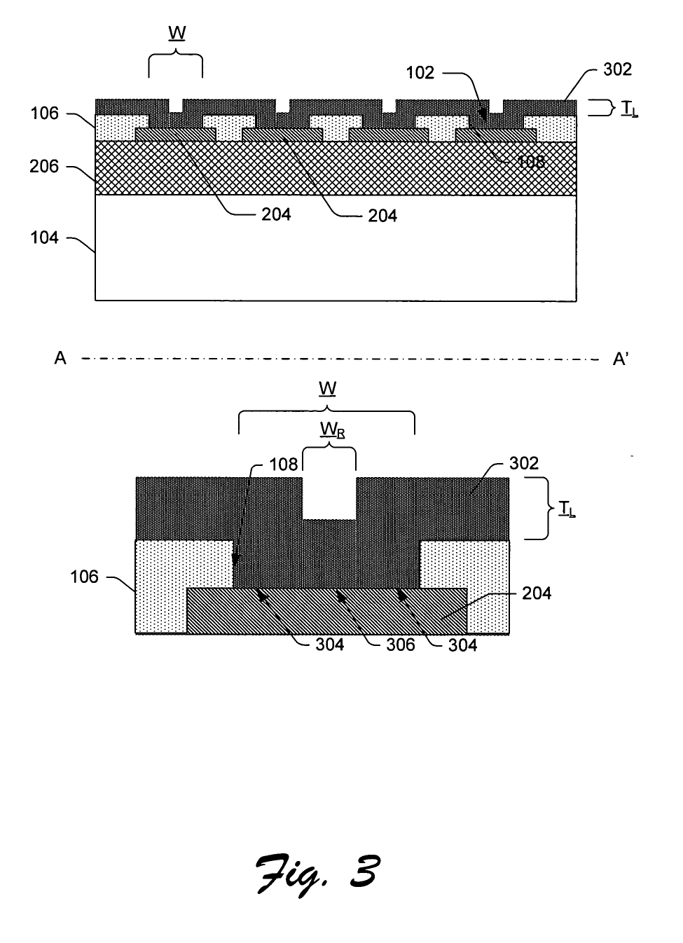

Referring to FIG. 3, a removable layer 302 of a layer thickness TL is formed over the features 102. The removable layer can be deposited with an alignment-independent technique, such as chemical vapor deposition (CVD). This deposition can be performed with a high degree of accuracy with well-known techniques. The removable layer can, for instance, be deposited to a layer thickness TL of about ninety nanometers with a variance in thickness of plus or minus one tenth of one nanometer.

In the ongoing memory device example, the removable layer is formed of a dielectric material, such as silicon oxide or silicon nitride.

Generally, as part of this formation of the removable layer 302, the layer thickness T_{L} conforms to the underlying structure 106 and so has a varying height based on dimensions of the underlying structure and its boundaries 108 that surround the feature 102. These varying heights of the removable layer occupy regions of each feature.

As shown in an expanded view in FIG. 3, the feature 102 has, in the width W dimension, two spacer precursor regions 304 and a reduced feature precursor region 306 over which the removable layer 302 resides.

Dimensions of these spacer precursor regions 304 and the reduced feature precursor region 306 are dependent on the layer thickness T_{L}. The dimension (e.g., the width) of the spacer precursor regions 304 is about equivalent to the layer thickness T_{L}.

In one embodiment (not illustrated), the layer thickness is formed at about forty-five percent of the size (e.g., width) of the feature 102 that is desired to be reduced. In this case, the spacer precursor regions 304 occupy about ninety percent of the feature's size in the width dimension, and the reduced feature precursor region 306 about ten percent.

In another embodiment, the layer thickness is formed at about forty percent of the size of the feature 102 that is desired to be reduced. In this case, the spacer precursor regions 304 occupy about eighty percent of the feature's size in that dimension, and the reduced feature precursor region 306 about twenty percent.

In the illustrated embodiment, the reduced feature precursor region's 306 reduced width W_{R} is based on the width W (here the original width) of the feature 102 and the widths of the spacer precursor regions 304. The reduced width W_{R} of the reduced feature precursor region 306 is about equal to the width W minus twice the layer thickness T_{L}.

Also in the illustrated embodiment, the feature's 102 width W is about 250 nanometers. The layer thickness T_{L} is formed to a thickness of about ninety nanometers (or thirty-six percent of the width W). Thus, the reduced width W_{R} of the reduced feature precursor region 306 is about seventy nanometers (250−(2*90)=70).

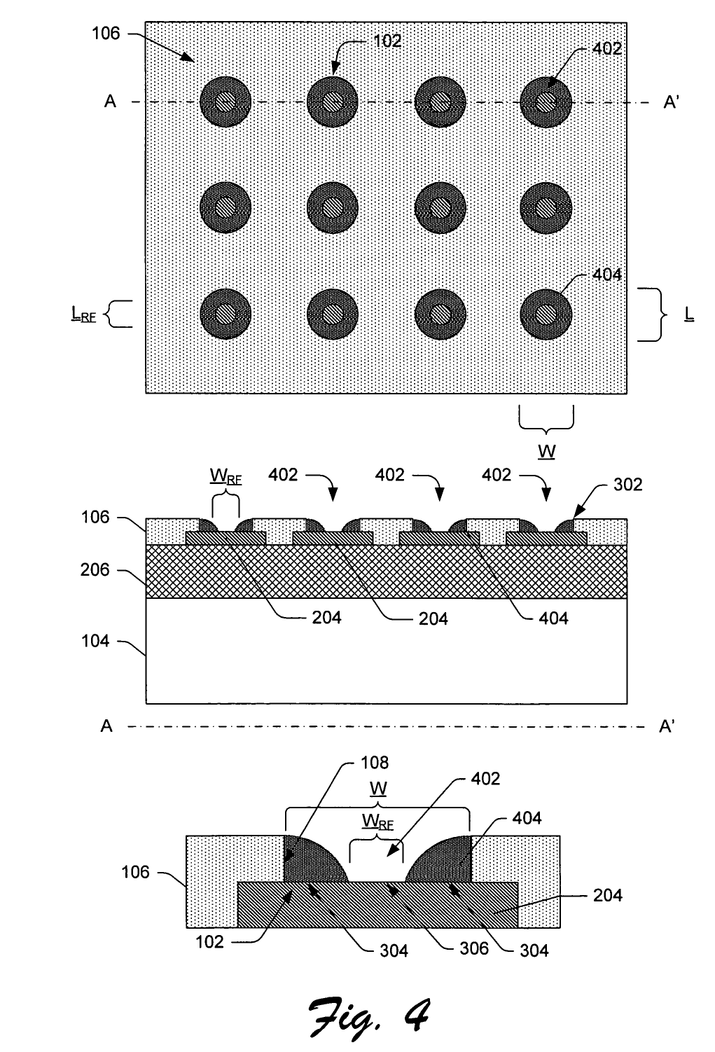

Referring to FIG. 4, a reduced feature 402 is formed. The reduced feature 402 can be formed from the feature 102 by removing parts of the removable layer 302 residing over the feature. These parts can comprise most of or substantially all of the reduced feature precursor region 306. The removable layer that is removed can be removed with anisotropic etching or another suitable technique. Well-known anisotropic etching techniques are alignment-independent, and can be controlled to a high level of accuracy. Thus, how much of the region 306 and the spacer precursor regions 304 are removed can be carefully controlled. This selective removal of part but not all of the removable layer 302 can be controlled to permit fabrication of the reduced feature 402 having carefully controlled dimensions, assuming that the original dimensions of the feature 102 were accurately formed.

Based on the exemplary embodiments described above, a size of the feature 102 can be reduced by ninety, eighty, and seventy-two (100−(2*36)=28) percent. This reduction in size of the feature is represented in the illustrated embodiment by the reduced feature 402. Size reductions more than ninety or less than seventy-two percent can also be performed. They can be performed by forming the removable layer 302 to a layer thicknesses T_{L} of greater than forty-five or less than thirty-six percent of the size to be reduced.

In the illustrated embodiment of the memory device, substantially all of removable layer 302 over the reduced feature precursor region 306 is removed. Enough of the removable layer 302 directly over the spacer precursor regions 304 is not removed to leave spacers 404. In this case, the size of the reduced feature precursor region 306 is substantially similar to the size of the reduced feature 402. Relatedly, the reduced width W_{R} of FIG. 3 is, in this case, substantially identical to a width W_{RF} of the reduced feature 402. The reduced feature 402 has the width W_{RF} and a length L_{RF}, both of about 70 nanometers. This represents a significant reduction from the original length L and width W of 250 nanometers.

In another embodiment, some of the removable layer 302 remains in the reduced feature precursor region 306. In this case, the reduced feature 402 may have a dimension that is smaller than the reduced feature precursor region 306 (not shown).

In still another embodiment, all of the removable layer 302 in the reduced feature precursor region 306 is removed and some of the spacer precursor region 304 near the region 306 has all of the removable layer 302 removed. In this case, the spacers 404 are not as large as the spacer precursor regions 304 and the reduced feature 402 has a dimension larger than the reduced feature precursor region 306 (not shown).

Fabricating The Memory Device With The Reduced Feature

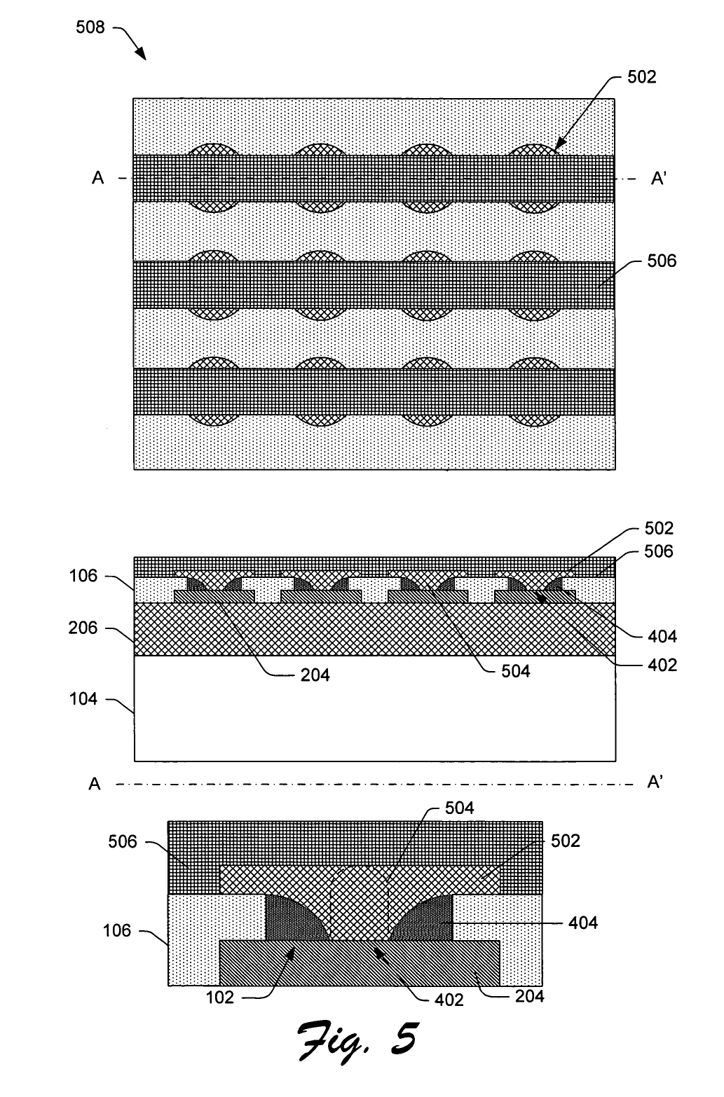

Referring to FIG. 5, memory media 502 is formed over the reduced features 402. The memory media can be formed using photolithography or other suitable techniques. The memory media that resides on the bottom electrodes 204 is active, while the other is not. A memory state of this active media 504 (marked with a dashed line in the expanded view) can be capable of being altered by electrical communication between the bottom electrodes 402 and top electrodes (described below). Conversely, the memory media 502 not residing over the bottom electrodes 402 is not active. Thus, the active media 504 has smaller dimensions than the memory media 502 that resides over the feature 102. These smaller dimensions, in this case a smaller area, affect how the memory device functions. This reduced area of the reduced feature 402 acts to reduce power output needed by the memory device and also can aid in making the device more consistent and robust.

In the illustrated embodiment, the active amount of the media 502 is reduced through these tools by about 92% ((70/2)ˆ2/(250/2) ˆ2=0.078). The memory media can comprise a phase change material, such as Indium Telluride (InTe) or Indium Selenide (InSe), a ferroelectric material, such as PZT (PbZrₓTi₁₋ₓO₃), SBT (SrBi₂Ta₂O₉), Bi₄Ti₃O₁₂, or other suitable memory materials.

Each of these memory devices can be formed individually or as a larger system. For a larger system of memory devices, such as a cross-bar memory device, the feature size reduction enabled by the tools can be performed for all of the devices in the system at one once. By so doing, these tools can permit consistent production and reduce cost.

Following formation of the memory media, the top electrodes 506 are formed over the active media 504 with suitable techniques. These top electrodes form an array of conductive structures capable of electrical communication with the active media. A passivation layer can also be formed over the top electrodes and the memory media, if desired (not shown). The result is a cross-bar memory device 508 having improved operating characteristics permitted by reduction of a feature size.

Although the invention is described in language specific to structural features and methodological steps, it is to be understood that the invention defined in the appended claims is not necessarily limited to the specific features or steps described. Rather, the specific features and steps disclosed represent exemplary forms of implementing the claimed invention.

What is claimed is:

1. A method comprising:
forming a cross-bar memory device by:
providing a pattern of features oriented over an array of conductive structures, each feature having an area that exposes one of the conductive structures;
forming a removable layer over the pattern of features;
removing part but not all of the removable layer to form one or more spacers over the features, the spacers substantially reducing each feature's area that is capable of exposing one of the conductive structures; and
forming memory media over the features' reduced areas.

2. The method of claim 1, further comprising forming a second array of second conductive structures, the second array capable of electrical communication with the memory media formed over the features' reduced areas.

3. The method of claim 1, wherein the act of forming memory media comprises forming the memory media of a ferroelectric material.

4. The method of claim 1, wherein the act of forming memory media comprises forming the memory media of a phase change material.

5. The method of claim 1, wherein the acts of forming the removable layer and removing are performed using only alignment-independent techniques.

6. The method of claim 1, wherein the act of forming the removable layer comprises forming the removable layer to a first height over one or more spacer precursor regions and a second, smaller height over a reduced feature precursor region, the first and second regions residing over each feature's area.

7. The method of claim 6, wherein the act of removing comprises removing substantially all of the removable layer over the reduced feature precursor region.

8. The method of claim 6, wherein the act of removing comprises forming the spacers by leaving a remainder of the removable layer over the spacer precursor regions.

9. The method of claim 1, wherein the spacers are formed reducing each feature's area by more than about ninety percent.

10. The method of claim 1, wherein the act of removing comprises reducing each feature's area to less than or about 7,500 square nanometers.

11. A cross-bar memory device comprising:
a first array of electrodes;
an array of structures disposed over the first array of electrodes, each structure defining a feature having a first area over a different electrode of the first array;
spacers disposed within the first area of each of the features, the spacers bounding a second, generally smaller area;
memory media disposed over the second area and in electrical communication with the first array of electrodes; and
a second array of electrodes disposed over the substrate and in electrical communication with the first array of electrodes effective to alter a memory state of the memory media.

12. The device of claim 11, wherein the memory media further resides over the spacers and the electrical communication is not effective to alter the memory state of the memory media residing over the spacers.

13. The device of claim 11, wherein each of the first areas is about nine or more times greater than the most proximate of the second areas.

14. The device of claim 11, wherein the memory media comprises a ferroelectric material.

15. The device of claim 11, wherein the memory media comprises a phase change material.

16. A method comprising:
forming a cross-bar memory device by:
forming a feature having a size in one dimension of less than or about 250 nanometers; and
reducing the size of the feature by about one half or more.

17. The method of claim 16, wherein the feature forms a depression in a structure, the structure having physical boundaries defining outer bounds of the size in the one dimension.

18. The method of claim 17, wherein the act of reducing the size comprises forming one or more spacers over the feature and at the physical boundaries.

19. The method of claim 16, wherein the act of reducing the size is performed using only alignment-independent techniques.

20. The method of claim 16, wherein the act of reducing the size comprises reducing the size by about two thirds or more.

21. The method of claim 16, wherein the act of reducing the size comprises reducing the size by about ninety percent or more.

22. The method of claim 16, wherein the act of reducing the size further comprises reducing the size in a second dimension by about one half of more.

23. The method of claim 16, wherein the act of reducing the size comprises:
forming a removable layer over the feature; and
removing the removable layer over part but not all of the feature.

24. The method of claim 23, wherein the act of forming the removable layer comprises forming the removable layer having a first height over one or more spacer precursor regions and a second, smaller height over a reduced feature precursor region, and the act of removing comprises forming spacer(s) over the spacer precursor region(s) by removing the removable layer over the reduced feature precursor region and leaving some of the removable layer over the spacer precursor region(s).

25. A method for decreasing a feature size, comprising:
forming an original feature having a size in a length or width dimension of between about 100 and about 1000 nanometers with a system capable of patterning features to a minimum size of less than or about the size of the original feature; and
reducing the size of the original feature below that of the minimum size of the system using an alignment-independent technique effective to create a reduced-size feature from the original feature.

26. The method of claim 25, wherein the act of reducing the size comprises forming spacers at outer bounds of the original feature.

27. The method of claim 25, wherein the size is less than or about 250 nanometers and the act of reducing the size comprises reducing the size by about two thirds or more.

28. The method of claim 25, wherein the act of reducing the size comprises:
forming a removable layer over the original feature; and
removing the removable layer over part but not all of the original feature.

29. The method of claim 28, wherein the act of forming the removable layer comprises forming the removable layer having a first height over one or more spacer precursor regions and a second, smaller height over a reduced feature precursor region, and the act of removing comprises forming spacer(s) over the spacer precursor region(s) by removing the removable layer over the reduced feature precursor region and leaving some of the removable layer over the spacer precursor region(s).

30. A method comprising:
forming a memory device by:
forming a feature having a size in one dimension of less than or about 1000 nanometers;
forming a removable layer over the feature; and
removing part but not all of the removable layer to form one or more spacers over the feature, the spacers substantially reducing the size in the one dimension.

31. The method of claim 30, wherein act of forming the feature comprises forming the size bounded by physical boundaries, and the act of removing comprises forming the spacers over the feature and at the physical boundaries.

32. The method of claim 31, wherein the act of forming the removable layer comprises forming the removable layer having a first height at a region where the physical boundaries and the feature meet, and a smaller, second height between the regions, and the act of removing comprises removing the removable layer between the regions.

33. The method of claim 30, wherein the acts of forming and removing comprise only alignment-independent techniques.

34. The method of claim 30, wherein the act of removing comprises forming spacers occupying, in total, one half of more of the size in the one dimension.

35. The method of claim 30, wherein the act of removing comprises forming second spacers substantially reducing a second size of the feature in a second dimension.

36. A method comprising:
forming a memory device by:
providing a feature having an area of less than or about 250,000 nanometers square;
reducing the area of the feature by ninety or more percent; and
forming memory media over the reduced area.

37. The method of claim 36, wherein the act of reducing the area comprises alignment-independent techniques.

38. The method of claim 36, wherein the act of reducing the area comprises forming one or more spacers over the area of the feature and at outer bounds of the area.

39. The method of claim 36, wherein the act of reducing the area comprises:
forming a removable layer over the feature; and
removing the removable layer over ten or less percent of the area.

40. The method of claim 39, wherein the act of forming the removable layer comprises forming the removable layer having a first height at outer bounds of the area of the feature and a second, smaller height bounded by the first height, and the act of removing comprises forming one or more spacers at the outer bounds of the area by removing substantially all of the removable layer having the second, smaller height.
